(19) United States
(12) Patent Application Publication
(10) Pub. No.: US 2014/0334160 A1
(43) Pub. Date: Nov. 13, 2014

(54) Light Extraction Substrate For OLED, and OLED Including The Same

(71) Applicant: SAMSUNG CORNING PRECISION MATERIALS CO., LTD., Gyeongsangbuk-do (KR)

(72) Inventors: Kiyeon Lee, ChungCheongNam-Do (KR); Kyungmin Yoon, ChungCheongNam-Do (KR); Youngseok Lee, ChungCheongNam-Do (KR); Jaeho Lee, ChungCheongNam-Do (KR)

(73) Assignee: SAMSUNG CORNING PRECISION MATERIALS CO., LTD., Gyeongsangbuk-do (KR)

(21) Appl. No.: 14/272,899

(22) Filed: May 8, 2014

(30) Foreign Application Priority Data
May 8, 2013 (KR) 10-2013-0051996

(51) Int. Cl. F21K 99/00

(52) U.S. Cl. CPC F21K 9/50
USPC 362/311.02; 362/355

(57) ABSTRACT

A light extraction substrate for an organic light-emitting device (OLED) which can improve the light extraction efficiency of an OLED, a method of fabricating the same and an OLED including the same. The light extraction substrate is disposed on one surface of an OLED through which light generated from the OLED is emitted outward. The light extraction substrate includes a base substrate, a light extraction layer disposed on the base substrate, and a number of crystallization particles disposed inside the light extraction layer. The light extraction layer is made of a glass frit that has a composition including ZnO, B₂O₃, SiO₂, MgO and Bi₂O₃.

### CROSS REFERENCE TO RELATED APPLICATION

The present application claims priority from Korean Patent Application Number 10-2013-0051996 filed on May 8, 2013, the entire contents of which are incorporated herein for all purposes by this reference.

### BACKGROUND OF THE INVENTION

1. Field of the Invention

The present invention relates to a light extraction substrate for an organic light-emitting device (OLED), a method of fabricating the same and an OLED including the same, and more particularly, to a light extraction substrate for an OLED which can improve the light extraction efficiency of an OLED, a method of fabricating the same and an OLED including the same.

2. Description of Related Art

In general, light emitting devices can be generally divided into organic light-emitting devices (OLEDs) in which a light-emitting layer is made of an organic matter and inorganic light-emitting devices (ILEDs) in which a light-emitting layer is made of an inorganic matter. Among them, OLEDs are self-emitting devices which generate light as excitons that are generated through the recombination of electrons injected through a cathode and holes injected through an anode emit energy. OLEDs have a variety of advantages, such as, self-emission, a wide viewing angle, a high resolution, natural color reproduction and rapid response.

Recently, active studies are underway in order to apply OLEDs to a variety of devices, such as portable information devices, cameras, watches, office equipment, information display windows of vehicles, televisions (TVs), displays, or illumination systems.

Methods for improving the luminous efficiency of OLEDs include a method of improving the luminous efficiency of a material that constitutes a light-emitting layer and a method of improving the light extraction efficiency at which light generated from the light-emitting layer is extracted.

The light extraction efficiency depends on the refractive indices of layers which form each OLED. In a typical OLED, when a ray of light generated from the light-emitting layer is emitted at an angle greater than a critical angle, the ray of light is totally reflected at the interface between a higher-refractivity layer, such as a transparent electrode layer, and a lower-refractivity layer, such as a substrate. This consequently lowers the light extraction efficiency, thereby lowering the luminous efficiency, which is problematic.

In fact, due to this problem of total reflection at the interface, only about 25% of light generated from the light-emitting layer of an OLED is emitted outward and about 75% of the light is lost.

In order to overcome this problem, a method of applying a mixture of a high refractive index frit and light-scattering particles on a glass substrate or a method of applying a light-scattering agent on a glass substrate and then applying a high refractive index frit on the light-scattering agent was used in the related art. However, according to these methods, when the frit applied on the glass substrate is being fired, the light-scattering particles may form protrusions which lower the flatness of the substrate. When the OLED is operating, current concentration may occur in a portion where the light-scattering particles protrude. In order to overcome this problem, a planarization layer was provided on the frit having the protrusions of the light-scattering particles. However, this processing is difficult and increases cost.

The information disclosed in the Background of the Invention section is provided only for enhancement of (or better) understanding of the background of the invention, and should not be taken as an acknowledgment or any form of suggestion that this information forms a prior art that would already be known to a person skilled in the art.

### RELATED ART DOCUMENT

Patent Document 1: Korean Patent No. 10-0565194 (Mar. 22, 2006)

### BRIEF SUMMARY OF THE INVENTION

Various aspects of the present invention provide a light extraction substrate for an organic light-emitting device (OLED) which can improve the light extraction efficiency of an OLED, a method of fabricating the same and an OLED including the same.

In an aspect of the present invention, provided is a light extraction substrate which is disposed on one surface of an OLED through which light generated from the OLED is emitted outward. The light extraction substrate includes a base substrate; a light extraction layer disposed on the base substrate; and a number of crystallization particles disposed inside the light extraction layer. The light extraction layer is made of a glass frit that has a composition including ZnO, B₂O₃, SiO₂, MgO and Bi₂O₃.

According to an embodiment of the present invention, the composition of the glass frit may include, by weight, 30 to 65% ZnO, 5 to 24% B₂O₃, 3 to 15% SiO₂, 1 to 5% MgO and 5 to 30% Bi₂O₃.

The refractive index of the light extraction layer may be 1.65 or higher.

The transmittance of the light extraction layer may be 50% or greater.

The number of crystallization particles may be randomly distributed inside the light extraction layer.

In another aspect of the present invention, provided is a method of fabricating a light extraction substrate which is disposed on one surface of an OLED through which light generated from the OLED is emitted outward. The method includes the following steps of: applying a frit paste on a base substrate; and firing the frit paste at a temperature that is equal to or lower than a strain point of the base substrate, forming a light extraction layer which has a number of crystallization particles therein on the base substrate.

According to an embodiment of the present invention, the step of applying the frit paste on the base substrate may include applying the frit paste that is produced by mixing a frit, a composition of which includes ZnO, B₂O₃, SiO₂, MgO and Bi₂O₃, into an organic solvent to which an organic binder is added.

The step of applying the frit paste on the base substrate may include applying the frit paste that is produced by mixing the frit, a composition of which includes, by weight, 30 to 65% ZnO, 5 to 24% B₂O₃, 3 to 15% SiO₂, 1 to 5% MgO and 5 to 30% Bi₂O₃, into an organic solvent to which an organic binder is added.

The step of firing the frit paste may include firing the frit paste at a temperature ranging from 470 to 670° C.

In a further aspect of the present invention, provided is an OLED including the above-mentioned light extraction substrate a substrate which is disposed on one surface through which light generated from the OLED is emitted outward.

According to embodiments of the present invention, the crystalline frit paste is printed on the glass substrate, and then is fired at a temperature that is equal to or lower than the strain point of the glass substrate. That is, a coating layer that includes a low-melting point crystalline glass is formed on the glass substrate, and then is heat-treated, by which the light extraction layer in which crystals particles are randomly precipitated is formed on the glass substrate. The precipitated crystals particles, i.e. the crystallization particles, can scatter light generated from the OLED when the light passes through the light extraction layer. This can consequently improve the light extraction efficiency of the OLED, allow the OLED to operate at a low current, reduce the power consumption of the OLED, and improve the luminance of a display or an illumination system that employs the OLED.

In addition, the light extraction layer having a superior surface roughness is produced through the softening and flowing of the frit during the firing, and can be applied not only as an external light extraction layer but also as an internal light extraction layer of the OLED. The refractive index of the glass frit is similar to or slightly lower than the refractive index of the transparent electrode made of indium tin oxide (ITO) which forms an anode of the OLED; this characteristic can be advantageous for the improvement of the light extraction efficiency.

Furthermore, since the crystallization particles are randomly distributed inside the light extraction layer due to the firing, it is possible to realize a predetermined level of transmittance.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view schematically showing a light extraction substrate for an OLED according to an exemplary embodiment of the invention;

FIG. 2 is a process flowchart showing a method of fabricating a light extraction substrate for an OLED according to an exemplary embodiment of the invention;

FIG. 3 is pictures showing a printed frit paste and a fired frit paste; and

FIG. 4 is electron microscopy pictures showing the states of crystallization particles according to heat treatment conditions.

### DETAILED DESCRIPTION OF THE INVENTION

Reference will now be made in detail to a light extraction substrate for an organic light-emitting device (OLED), a method of fabricating the same and an OLED including the same according to the present invention, embodiments of which are illustrated in the accompanying drawings and described below, so that a person skilled in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

As shown in FIG. 1, a light extraction substrate 100 for an organic light-emitting device (OLED) according to an exemplary embodiment of the present invention is a functional substrate which improves the light extraction efficiency of the OLED in order to increase the luminance of a display or an illumination system that employs the OLED. For this, the light extraction substrate 100 for an OLED according to this exemplary embodiment is disposed on one surface of the OLED through which light generated from the OLED is emitted outward.

The light extraction substrate 100 for an OLED includes a base substrate 110, a light extraction layer 120 and a number of crystallization particles 130.

The base substrate 110 is the substrate which supports the light extraction layer 120 which is formed on one surface of the base substrate 110. The base substrate 110 is also disposed in front of the OLED, i.e. in the direction in which light generated from the OLED is emitted outward, and allows the generated light to exit through it. The base substrate 110 also serves as an encapsulation substrate which protects the OLED from the external environment. The base substrate 110 can be made of transparent glass that has a low coefficient of thermal expansion (CTE) such that it is not deformed during firing of the light extraction layer 120 made of a glass frit and has a low strain point in order to facilitate crystallization of the glass frit during the firing. For example, the base substrate 110 can be made of borosilicate glass.

The light extraction layer 120 is formed on the base substrate 110. The light extraction layer 120 serves to diversify or increase paths along which light generated from the OLED scatters, thereby improving the light extraction efficiency of the OLED. The light extraction layer 120 has therein a number of crystallization particles 130 which scatter light. Specifically, this structure can scatter the light that is generated from the OLED and passes through the light extraction layer 120 using the number of crystallization particles 130 which acts as a light diffuser. This can consequently improve the light extraction efficiency, operate the OLED at a low current, reduce the power consumption of the OLED, and thus increase the luminance of a display or an illumination system that employs the OLED.

The crystallization particles 130 according to this exemplary embodiment can be randomly distributed. When the crystallization particles 130 are randomly distributed inside the light extraction layer 120, the light extraction layer 120 can scatter light through the crystallization particles 130 while realizing a predetermined level of transmittance, for example, a transmittance of 50% or greater.

The light extraction layer 120 according to this exemplary embodiment is made of a glass frit. The composition of the glass frit includes ZnO, B₂O₃, SiO₂, MgO Bi₂O₃. For example, the composition of the glass frit may include, by weight, 30 to 65% ZnO, 5 to 24% B₂O₃, 3 to 15% SiO₂, 1 to 5% MgO and 5 to 30% Bi₂O₃. What the contents of ingredients mean will be described in detail in relation to the method of fabricating a light extraction substrate for an OLED which will be described later.

The number of crystallization particles 130 that are randomly distributed inside the light extraction layer 120 is formed by firing the frit having the above-mentioned composition. When this frit is fired, due to the softening and flowing of the frit, the surface of the light extraction layer 120 has a high flatness, i.e. a superior surface roughness. The firing of the frit will be described in more detail in relation to the method of fabricating a light extraction substrate for an OLED which will be described later.

The light extraction layer 120 has the number of crystallization particles 130 disposed therein, has the superior surface roughness, and is made of the glass frit having the above-mentioned composition. The refractive index of the light extraction layer 120 is 1.65 or higher that is similar to the refractive index of a transparent electrode made of indium tin oxide (ITO) which forms an anode of the OLED. Therefore, when the light extraction substrate 100 according to this exemplary embodiment is applied as an internal light extraction substrate of the OLED, the light extraction layer 120 adjoins to the anode that has the similar refractive index, and thus can further improve the light extraction efficiency. Since the surface of the light extraction layer 120 forms the high-flatness surface, when the light extraction layer 120 adjoins to the anode of the OLED, it is possible to prevent current from being concentrated in the adjoining portion.

Although not shown in the figures, the OLED which includes the light extraction substrate 100 including the base substrate 110, the light extraction layer 120 and the number of crystallization particles 130 can have a multilayer structure which is sandwiched between the light extraction substrate 100 according to this exemplary embodiment and another substrate which faces the light extraction substrate 100, and includes an anode, an organic light-emitting layer and a cathode which are stacked one on another. The anode can be made of a metal or an oxide, such as gold (Au), indium (In), tin (Sn) or indium tin oxide (ITO), which has a significant work function in order to facilitate the hole injection. The cathode can be implemented as a metal thin film made of, for example, Al, Al:Li or Mg:Ag, having a smaller work function in order to facilitate the electron injection. In a top emission type OLED, the cathode can have a multilayer structure that includes a semitransparent electrode of a metal thin film made of Al, Al:Li or Mg:Ag and a transparent electrode of an oxide thin film made of, for example, indium tin oxide (ITO) in order to facilitate the transmission of light generated from the organic light-emitting layer. The organic light-emitting layer includes a hole injection layer, a hole transport layer, a light-emitting layer, an electron transport layer and an electron injection layer which are sequentially stacked on the anode.

When a forward voltage is applied between the anode and the cathode of this structure, electrons from the cathode migrate to the light-emitting layer through the electron injection layer and the electron transport layer, and holes from the anode migrate to the light-emitting layer through the hole injection layer and the hole transport layer. The electrons and holes that have migrated into the light-emitting layer recombine with each other, thereby generating excitons. When these excitons transit from an excited state to a ground state, light is emitted. The brightness of the light emitted is proportional to the amount of current that flows between the anode and the cathode.

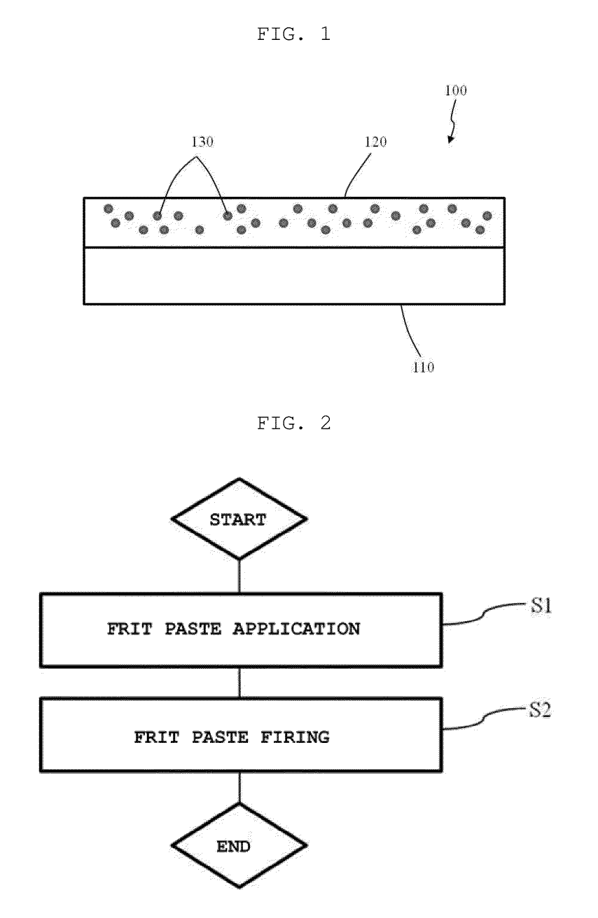

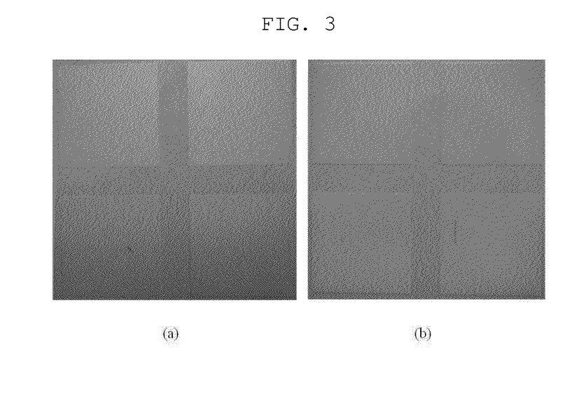

Reference will now be made to a method of fabricating a light extraction substrate for an OLED according to an exemplary embodiment of the present invention in conjunction with FIG. 2. As for the reference numerals of individual elements, those in FIG. 1 will be referred to.

As shown in FIG. 2, the method of fabricating a light extraction substrate for an OLED according to this exemplary embodiment is the method of fabricating the light extraction substrate 100 which is disposed on one surface of the OLED through which light generated from the OLED is emitted outward, and includes a frit paste application step S1 and a frit paste firing step S2.

First, the frit paste application step S1 is the step of applying a frit paste on the base substrate 110. At the frit paste application step S1, for instance, the frit paste is applied on the base substrate 110 made of borosilicate glass, for example, by screen printing. The frit paste that is applied on the base substrate 110 at the frit paste application step S1 can be produced by mixing a frit, the composition of which includes ZnO, B₂O₃, SiO₂, MgO and Bi₂O₃, into an organic solvent to which an organic binder is added. In this case, the frit paste that is applied on the base substrate 110 at the frit paste application step S1 can be produced by mixing a frit, the composition of which includes, by weight, 30 to 65% ZnO, 5 to 24% B₂O₃, 3 to 15% SiO₂, 1 to 5% MgO and 5 to 30% Bi₂O₃, into an organic solvent to which an organic binder is added. At a ZnO content less than 30% by weight, crystallization is difficult in the subsequent firing process. A ZnO content greater than 65% by weight leads to excessive crystallization, and thus it is difficult to set the transmittance of the light extraction layer 120 that is to be formed to an intended level. In addition, at a B₂O₃ content less than 5% by weight, vitrification is difficult. At a B₂O₃ content greater than 24% by weight, haze is high, transmittance is lowered, and crystallinity control is difficult. SiO₂ is an element of glass. SiO₂ is not effective at a content less than 3% by weight, and raises the softening point of the frit at a content greater than 15% by weight. A Bi₂O₃ content less than 5% by weight raises the softening point of the frit. The firing must be performed at a temperature higher than the strain point of the base substrate 110 made of borosilicate glass, and in this case, the base substrate 110 may be deformed. A Bi₂O₃ content greater than 30% by weight lowers the softening point of the frit. However, there is a problem in that crystals are precipitated during the process of melting the glass into the frit. In addition, MgO can accelerate crystallization when added at 1 to 5% by weight.

The organic solvent can be implemented as at least one selected from among, but not limited to, butyl carbitol acetate (BCA), α-terpineol (α-TPN), dibutyl phthalate (DBP), ethyl acetate, β-terpineol, cyclohexanone, cyclopentanone, hexylene glycol, high boiling point alcohol and mixtures of alcohol ester.

In addition, the organic binder can be implemented as at least one selected from among, but not limited to, ethyl cellulose, ethylene glycol, propylene glycol, ethyl hydroxyethyl cellulose, phenolic resin, mixtures of ethyl cellulose and phenolic resin, ester polymer, methacrylate polymer, methacrylate polymer of lower alcohol and monobutyl ether of ethylene glycol monoacetate.

Subsequently, the frit paste firing step S2 is the step of firing the frit paste applied on the base substrate 110. At the frit paste firing step S2, the frit paste is fired at a temperature that is equal to or lower than the strain point of the base substrate 110. Since the base substrate 110 is made of borosilicate glass according to this exemplary embodiment, the frit paste firing step S2 can fire the frit paste at a temperature ranging from 470 to 670° C. for about 30 minutes.

When the frit paste is fired in this manner, the light extraction layer 120 made of the glass frit is formed on the base substrate 110, in which the number of crystallization particles 130 are randomly distributed inside the light extraction layer 120. The light extraction layer 120 and the base substrate 110 form the light extraction substrate 100 for an OLED according to an exemplary embodiment of the invention.

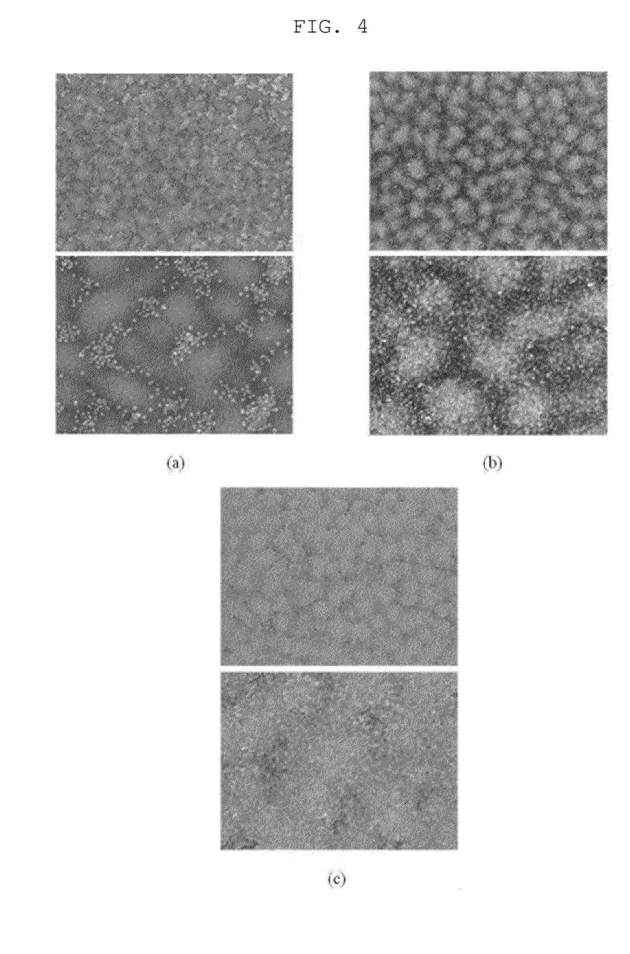

FIG. 3 is pictures showing a printed frit paste and a fired frit paste. Since the brightness of the fired frit paste (b) is higher than that of the printed frit paste (a), it can be visually confirmed that crystallization occurred when the frit paste was fired at a temperature ranging from 470 to 670° C. for about 30 minutes.

FIG. 4 is electron microscopy pictures showing the states of crystallization particles according to heat treatment conditions. In FIG. 4, part (a) shows the state of crystallization particles that were heat-treated at 550° C. for 30 minutes, part (b) shows the state of crystallization particles that were heat-treated at 590° C. for 30 minutes, and part (c) shows the state of crystallization particles that were heat-treated at 630° C. for 30 minutes. As shown in these pictures, the geometry, size and crystallinity (density) of the crystallization particles differ depending on the heat treatment temperatures. This explains that the characteristics of the crystallization particles can be controlled by adjusting the heat treatment temperature during the firing of the frit paste. This means that the light extraction level of an OLED can be controlled as required.

TABLE 1

| | Ex. 1 | Ex. 2 | Ex. 3 | Ex. 4 | Ex. 5 | Ex. 6 |
|---|---|---|---|---|---|---|
| ZnO (wt %) | 43 | 40 | 59 | 55 | 59 | 47 |
| B₂O₃ (wt %) | 21 | 20 | 21 | 20 | 18 | 24 |
| SiO₂ (wt %) | 6 | 10 | 10 | 10 | 7 | 6 |
| Bi₂O₃ (wt %) | 28 | 27 | 5 | 10 | 13 | 20 |
| MgO (wt %) | 2 | 3 | 5 | 5 | 3 | 3 |
| Crystallization | 530 | 560 | 660 | 620 | 610 | 580 |
| Temperature | | | | | | |
| (° C.) | | | | | | |
| Refractive | 1.831 | 1.791 | 1.686 | 1.735 | 1.762 | 1.783 |
| index | | | | | | |
| Transmittance | 78 | 75 | 62 | 65 | 68 | 72 |
| (%) | | | | | | |

Table 1 presents the results obtained by forming light extraction layers made of a glass frit at different compositions and crystallization temperatures according to examples. In all of Example 1 to Example 6, a high refractive index of 1.68 or higher was measured, and a superior transmittance of 60% or greater was obtained.

The foregoing descriptions of specific exemplary embodiments of the present invention have been presented with respect to the drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A light extraction substrate which is disposed on one surface of an organic light-emitting device through which light generated from the organic light-emitting device is emitted outward, comprising:
a base substrate;
a light extraction layer disposed on the base substrate; and
a number of crystallization particles disposed inside the light extraction layer,
wherein the light extraction layer is made of a glass frit that has a composition including ZnO, B₂O₃, SiO₂, MgO and Bi₂O₃.

2. The light extraction substrate according to claim 1, wherein the composition of the glass frit includes, by weight, 30 to 65% ZnO, 5 to 24% B₂O₃, 3 to 15% SiO₂, 1 to 5% MgO and 5 to 30% Bi₂O₃.

3. The light extraction substrate according to claim 1, wherein a refractive index of the light extraction layer is 1.65 or higher.

4. The light extraction substrate according to claim 1, wherein a transmittance of the light extraction layer is 50% or greater.

5. The light extraction substrate according to claim 1, wherein the number of crystallization particles are randomly distributed inside the light extraction layer.

6. An organic light-emitting device comprising the light extraction substrate as claimed in claim 1 as a substrate which is disposed on one surface through which light generated from the organic light-emitting device is emitted outward.
